(19) United States
(12) Patent Application Publication
(10) Pub. No.: US 2007/0007583 A1
(43) Pub. Date: Jan. 11, 2007

(54) Gate structure and related non-volatile memory device and method

(76) Inventors: Sung-Hae Lee, Suwon-si (KR); Ju-Wan Lim, Seoul (KR); Jae-Young Ahn, Seongnam-si (KR); Jin-Tae Noh, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/474,429

(22) Filed: Jun. 26, 2006

(30) Foreign Application Priority Data
Jul. 11, 2005 (KR) 2005-62150

(51) Int. Cl. H01L 29/792

(52) U.S. Cl. 257/324

(57) ABSTRACT

A gate structure adapted for use in a SONOS device unit cell is disclosed. The gate structure comprises a charge trap insulator and a single electrode. The charge trap insulator comprises a multilayer structure comprising a first silicon oxide layer, a silicon nitride layer, and a second silicon oxide layer. The single electrode is formed on the charge trap insulator, comprises a P-type impurity receptive semiconductor material, and is doped with P-type impurities.

### BACKGROUND OF THE INVENTION

1. Field of the Invention

Embodiments of the invention relate to a gate structure, a floating trap type non-volatile memory device comprising the gate structure, and a method of manufacturing the floating trap type non-volatile memory device. More particularly, embodiments of the invention relate to a SONOS device in which the unit cell of the SONOS device comprises a gate structure comprising a single electrode, and a method of manufacturing the same.

This application claims priority to Korean Patent Application No. 2005-62150, filed on Jul. 11, 2005, the subject matter of which is hereby incorporated by reference in its entirety.

2. Description of the Related Art

A non-volatile memory device is classified as either a floating gate type or floating trap type non-volatile memory device in accordance with the cell structure of the device. Floating trap type non-volatile memory devices are widely known as silicon oxide-nitride-oxide semiconductor (SONOS) devices.

A unit cell of a floating gate type non-volatile memory device comprises a tunnel oxide layer, a floating gate, a dielectric layer, and a control gate, which are sequentially stacked on a semiconductor substrate. Data is programmed into a unit cell of a floating gate type non-volatile memory device by moving electrons from the substrate into the floating gate through the tunnel oxide layer. Accordingly, a slight breakdown of the tunnel oxide layer causes electrons to be discharged from the floating gate causing the unit cell to be inadvertently erased. So, the tunnel oxide layer needs to be thick enough to prevent the discharge of electrons due to breakdown of the tunnel oxide layer. However, when the tunnel oxide layer is very thick, the unit cell requires a high operation voltage and a complex peripheral circuit to function. For these reasons, the degree of integration of the floating gate type non-volatile memory device is limited.

In contrast, a unit cell of a SONOS device comprises a charge trap insulator adapted to trap electrons and a single electrode formed on the charge trap insulator. The charge trap insulator comprises a multilayer structure comprising a first silicon oxide layer, a silicon nitride layer, and a second silicon oxide layer sequentially stacked on a semiconductor substrate. Data is programmed into the unit cell of the SONOS device by storing electrons in a trap of the charge trap insulator, wherein the trap is disposed between the substrate and the second silicon oxide layer. In particular, electrons are stored in a deep level trap of the silicon nitride layer of the SONOS device, and the first silicon oxide layer is relatively thin compared to the tunnel oxide layer of a floating gate type non-volatile memory device. A relatively thin first silicon oxide layer requires a low operation voltage and a relatively simple peripheral circuit, so the degree of integration of the SONOS device is more readily increased than the degree of integration of a floating gate type non-volatile memory device.

An exemplary SONOS device is disclosed in U.S. Pat. No. 6,501,681, the subject matter of which is incorporated by reference. As will be noted with respect to this conventional SONOS device, when data stored in the constituent unit cell is erased, electrons stored in the silicon nitride layer are not completely discharged. This result is contrary to the expected result. That is, when erasing data from a unit cell of the conventional SONOS device, all of the electrons stored in the silicon nitride layer should move into the substrate through the first silicon oxide layer due to the so-called Fowler-Nordheim tunneling effect. For an erase operation to be successful, all electrons should be removed from the silicon nitride layer. However, electrons remain in the silicon nitride layer of the unit cell of the conventional SONOS device after an erase operation has been performed because, during the erase operation, electrons move from the single electrode into the silicon nitride layer through the second oxide layer. In an extreme case, the number of electrons that move into the silicon nitride layer from the single electrode may be larger than the number of electrons discharged from the silicon nitride layer into the substrate, which would result in the unit cell remaining programmed after an erase operation has been performed.

In particular, when the single electrode of the unit cell is doped with elements from Group V of the periodic table, such as phosphorus (P) and arsenic (As), electrons are readily generated from the single electrode as charge carriers, and the silicon nitride layer will store electrons even after an erase operation is performed on the unit cell of the SONOS device. As a result, the conventional SONOS device is subject to non-trivial malfunctions.

### SUMMARY OF THE INVENTION

Accordingly, the present invention provides a gate structure comprising a charge trap insulator from which electrons are completely discharged when data is erased from a SONOS device unit cell comprising the gate structure. In this context, the phrase “completely discharged” means only an insignificant number of electrons, at most, will remain following an erase operation.

In one embodiment, the invention provides a gate structure comprising a charge trap insulator and a single electrode. The charge trap insulator comprises a multilayer structure comprising a first silicon oxide layer, a silicon nitride layer, and a second silicon oxide layer. The single electrode is formed on the charge trap insulator, comprises a P-type impurity receptive semiconductor material, and is doped with P-type impurities.

In another embodiment, the invention provides a non-volatile memory device comprising a semiconductor substrate, source/drain regions disposed at a surface portion of the substrate and doped with first type impurities, a channel region disposed at a surface of the substrate and between the source/drain regions, and a gate structure formed on the channel region. The gate structure comprises a charge trap insulator comprising a multilayer structure comprising a first silicon oxide layer, a silicon nitride layer, and a second silicon oxide layer; and a single electrode formed on the charge trap insulator, comprising a P-type impurity receptive semiconductor material, and doped with P-type impurities.

In still another embodiment, the invention provides a method of manufacturing a non-volatile memory device comprising sequentially forming a first thin layer comprising silicon oxide, a second thin layer comprising silicon nitride, and a third thin layer comprising silicon oxide on a semiconductor substrate, forming a fourth thin layer on the third thin layer, wherein the fourth thin layer comprises a P-type impurity receptive semiconductor material, and doping the fourth thin layer with P-type impurities. The method further comprises sequentially and partially etching the fourth thin layer, the third thin layer, the second thin layer, and the first thin layer to form a gate structure on the semiconductor substrate comprising a single electrode and a charge trap insulator, wherein the charge trap insulator comprises a first silicon oxide layer, a silicon nitride layer, and a second silicon oxide layer; and implanting first type impurities into the substrate to form source/drain regions at surface portions of the substrate near the gate structure.

### BRIEF DESCRIPTION OF THE DRAWINGS

Embodiments of the invention will be described with reference to the accompanying drawings, in which like reference symbols refer to like or similar elements throughout. In the drawings:

FIG. 1 is a cross-sectional view of a gate structure in accordance with an exemplary embodiment of the present invention;

FIG. 2 is a graph showing discharge characteristics of a first SONOS device comprising a first sample electrode, in which the charge carriers are holes, and a second SONOS device comprising a second sample electrode, in which the charge carriers are electrons;

FIG. 3 is a cross-sectional view illustrating a SONOS device unit cell in accordance with an exemplary embodiment of the present invention;

FIG. 4 is an energy band diagram for the SONOS device unit cell of FIG. 3 when erasing data from the SONOS device unit cell; and

FIGS. 5A to 5E are cross-sectional views illustrating processing steps for a method of manufacturing the SONOS device unit cell of FIG. 3.

### DESCRIPTION OF THE EXEMPLARY EMBODIMENTS

In the drawings, the size and relative sizes of layers and regions may be exaggerated for clarity. Also, it will be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be referred to a second element, component, region, layer, or section without departing from the scope of the present invention.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the invention are described herein with reference to cross-section illustrations that are schematic illustrations of idealized embodiments (and intermediate structures) of the invention. As such, variations from the shapes of the illustrations as a result of, for example, manufacturing techniques and/or tolerances, are to be expected. Thus, embodiments of the invention should not be construed as being limited to the specific shape of regions illustrated herein, but also encompass other shapes that may result from variances in manufacturing processes. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

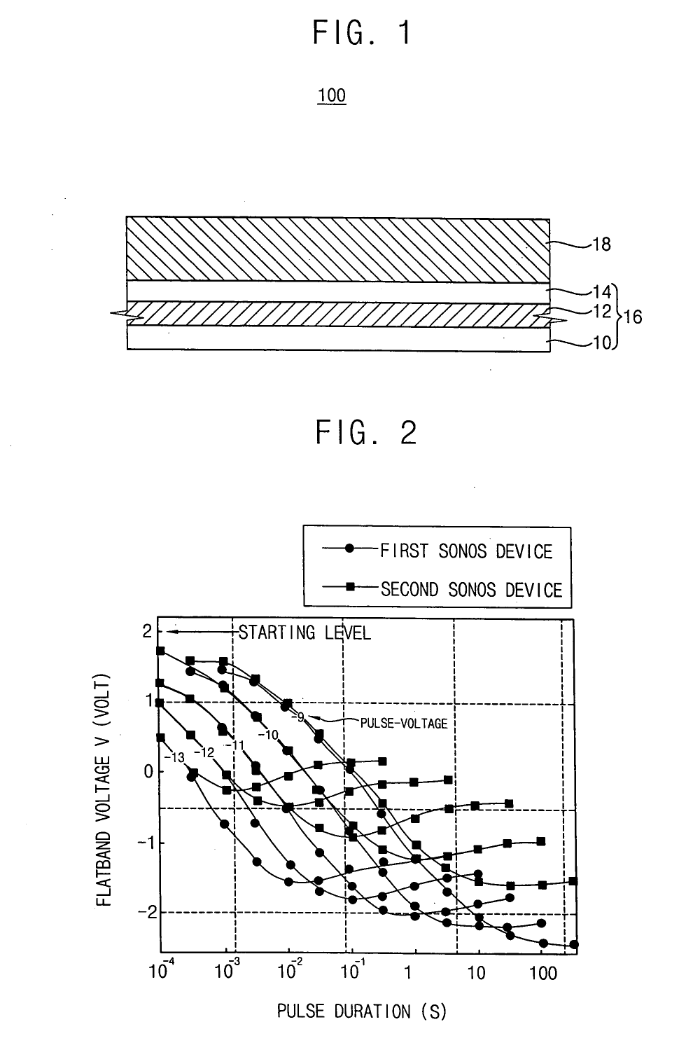

FIG. 1 is a cross-sectional view of a gate structure in accordance with an exemplary embodiment of the present invention.

Referring to FIG. 1, a gate structure 100 of the illustrated embodiment comprises a charge trap insulator 16 and a single electrode 18. Gate structure 100 may be used, for example, as a gate electrode of a floating trap type non-volatile memory device, (e.g., a SONOS device).

In one embodiment, charge trap insulator 16 comprises a multilayer structure comprising a first silicon oxide layer 10, a silicon nitride layer 12, and a second silicon oxide layer 14. First silicon oxide layer 10 corresponds to a tunnel layer adapted to provide an energy barrier for tunneling electrons, and silicon nitride layer 12 corresponds to a storage layer adapted to store electrons. Second silicon oxide layer 14 corresponds to a shield layer adapted to prevent the voltage apparent on single electrode 18 from being applied to silicon nitride layer 12.

Single electrode 18 is formed on charge trap insulator 16. In the illustrated embodiment, single electrode 18 is formed on second silicon oxide layer 14 of charge trap insulator 16. Additionally, single electrode 18 comprises a P-type impurity receptive semiconductor material. As used herein, the term “P-type impurity receptive semiconductor material” means a semiconductor material that is relatively receptive to doping with impurities adapted to generate holes as charge carriers. For example, a composition of silicon and germanium is three to five times more receptive to the doping with P-type impurities than polysilicon. Accordingly, in one illustrated embodiment, the P-type impurity receptive semiconductor material comprises a composition of silicon and germanium.

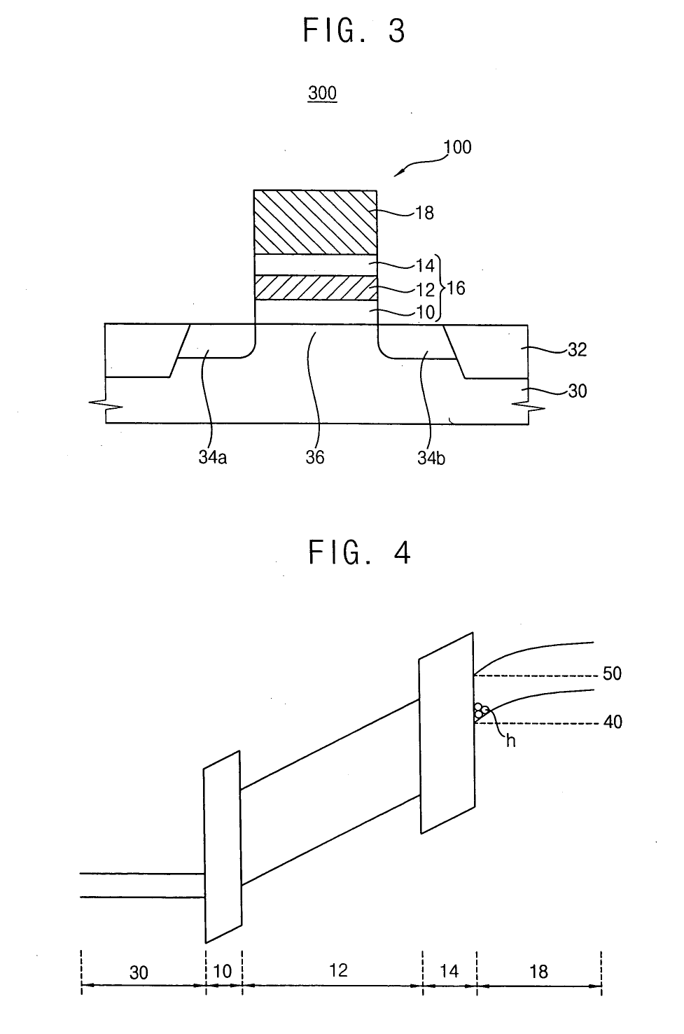

FIG. 2 is a graph showing discharge characteristics for a first SONOS device comprising a first sample electrode, in which the charge carriers are holes, and a second SONOS device comprising a second sample electrode, in which the charge carriers are electrons. In FIG. 2, the first sample electrode of the first SONOS device is doped with boron (B), and a plurality of holes function as the charge carriers in the first sample electrode of the first SONOS device, and the second sample electrode of the second SONOS device is doped with phosphorus (P), and a plurality of electrons function as the charge carriers in the second sample electrode of the second SONOS device. In addition, in the graph of FIG. 2, the horizontal axis represents the pulse duration time for each SONOS device in units of seconds, the vertical axis represents the flat-band voltage for each SONOS device in units of volts; and, as indicated in the key of the graph in FIG. 2, lines bearing circular characters (“•”) indicate the discharge characteristics of the first SONOS device, and lines bearing square characters (“▪”) indicate the discharge characteristics of the second SONOS device.

Referring to FIG. 2, the higher the applied voltage and the longer the pulse duration time, the less the electrons are discharged from the silicon nitride layer of the charge trap insulator in both the first and second SONOS devices. That is, the higher the applied voltage and the longer the pulse duration time, the more electrons remain in the silicon nitride layer of the charge trap insulator in both the first and second SONOS devices. However, FIG. 2 clearly shows that the discharge characteristics of the first SONOS device are much superior to that of the second SONOS device. Based on the above results, single electrode 18 of the embodiment illustrated in FIG. 1 comprises a P-type impurity receptive semiconductor material. In particular, compositions of silicon and germanium are highly receptive to the doping of P-type impurities, so a sufficient amount of P-type impurities may be doped into single electrode 18 comprising the composition of silicon and germanium. Elements in Group III of the periodic table, such as boron (B), are examples of impurities from which holes may be generated, and the impurities in Group III are referred to as P-type impurities.

In accordance with the embodiment illustrated in FIG. 1, gate structure 100 comprises a charge trap insulator 16 comprising first silicon oxide layer 10, silicon nitride layer 12, and second silicon oxide layer 14; and single electrode 18 comprising a P-type impurity receptive semiconductor material comprising a composition of silicon and germanium doped with P-type impurities such as boron (B).

When a SONOS device comprises gate structure 100 of the illustrated embodiment as a gate electrode, electrons do not move into charge trap insulator 16 from single electrode 18 because holes are much more abundant in single electrode 18 as charge carriers, and the number of electrons in single electrode 18 is sufficiently reduced.

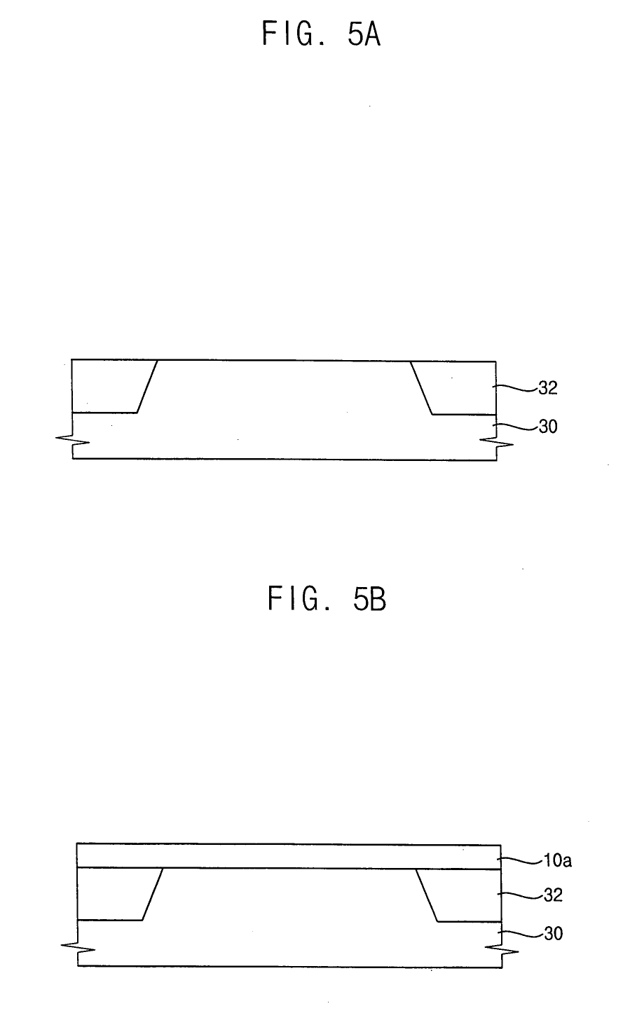

FIG. 3 is a cross-sectional view illustrating a SONOS device unit cell in accordance with an exemplary embodiment of the present invention. SONOS device unit cell 300 of FIG. 3 comprises gate structure 100 of FIG. 1, and like reference symbols indicate like or similar elements in FIGS. 1 and 3.

Referring to FIG. 3, SONOS device unit cell 300 comprises gate structure 100 of FIG. 1 formed on a semiconductor substrate 30. Semiconductor substrate 30 may be a silicon substrate, silicon-on-insulator (SOI) substrate, a germanium substrate, a germanium-on-insulator (GOI) substrate, a silicon-germanium substrate, or an epitaxial substrate comprising an epitaxial layer formed by a selective epitaxial growth (SEG) process. In the illustrated embodiment of FIG. 3, semiconductor substrate 30 is a silicon substrate. As another exemplary embodiment, when SONOS device unit cell 300 is formed into a stacked structure, it may be preferable for semiconductor substrate 30 to be an epitaxial substrate. Hereinafter, semiconductor substrate 30 will be referred to as substrate 30.

A device isolation layer 32 is formed on substrate 30, thereby defining an active region and a field region in substrate 30. Device isolation layer 32 may comprise a field oxide layer or a trench device isolation layer. In the illustrated embodiment, the trench device isolation layer is formed in substrate 30 to increase the degree of integration of the SONOS memory device.

Source/drain regions 34a and 34b are formed at surface portions of substrate 30 near gate structure 100 on substrate 30 by implanting impurities into the surface of substrate 30. The impurities of source/drain regions 34a and 34b comprise N-type impurities, such as elements in Group V of the periodic table. Examples of N-type impurities are phosphorus (P), arsenic (As), etc., which can be used alone or in a combination thereof.

A channel region 36 is formed at a surface portion of substrate 30 between source/drain regions 34a and 34b under gate structure 100.

As shown in FIG. 1, gate structure 100 comprises a charge trap insulator 16 and single electrode 18 formed on charge trap insulator 16. Charge trap insulator 16 comprises first silicon oxide layer 10, silicon nitride layer 12, and second silicon oxide layer 14; and single electrode 18 comprises a P-type impurity receptive semiconductor material. In the illustrated embodiment of FIG. 3, the P-type impurity receptive semiconductor material comprises a composition of silicon and germanium, and the P-type impurities comprise boron (B).

Hereinafter, an operation of SONOS device unit cell 300 comprising gate structure 100 comprising charge trap insulator 16 and single electrode 18 will be described in detail.

Data (i.e., storage data) is programmed into SONOS device unit cell 300 through the following process. Substrate 30 is connected to a ground potential initially and a positive voltage (V>0) is applied to single electrode 18. Then, a first electric field is generated between substrate 30 and single electrode 18, and a Fowler-Nordheim current passes through first silicon oxide layer 10 of charge trap insulator 16 from substrate 30. As a result, electrons in channel region 36 between source/drain regions 34a and 34b tunnel through an energy barrier of first silicon oxide layer 10 and move into silicon nitride layer 12 through the Fowler-Nordheim current. An energy barrier of second silicon oxide layer 14 prevents the electrons in silicon nitride layer 12 from moving into single electrode 18. Thus, the electrons are trapped in silicon nitride layer 12, and data is thereby programmed in SONOS device unit cell 300.

Data is erased from SONOS device unit cell 300 through the following process. Substrate 30 is connected to a ground potential initially and a negative voltage (V<0) is applied to single electrode 18. Then, a second electric field having a direction opposite than that of the first electric field is generated between substrate 30 and single electrode 18, and a Fowler-Nordheim current passes through first silicon oxide layer 10 of charge trap insulator 16 from silicon nitride layer 12. As a result, electrons in silicon nitride layer 12 tunnel through the energy barrier of first silicon oxide layer 10 and move into substrate 30 through the Fowler-Nordheim current. As a result, all of the electrons in silicon nitride layer 12 are discharged from silicon nitride layer 12 into substrate 30, thereby erasing the stored data from SONOS device unit cell 300.

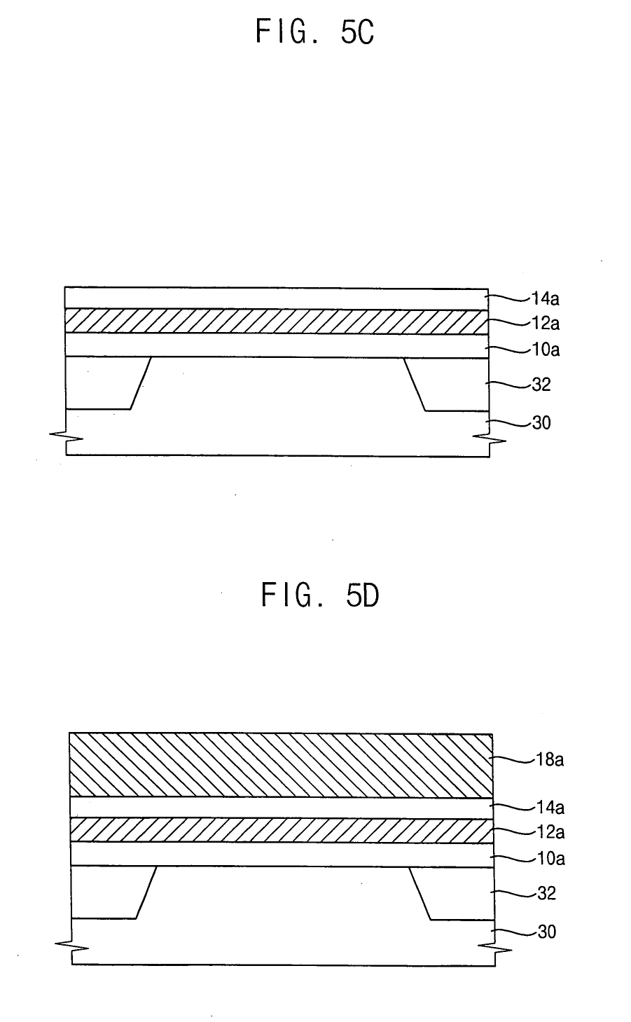

FIG. 4 is an energy band diagram for SONOS device unit cell 300 of FIG. 3 when erasing data from SONOS device unit cell 300.

Referring to FIG. 4, when single electrode 18 comprises an abundance of electrons as charge carriers, the electrons are positioned around a Fermi level of an N-type dopant 50, so that the electrons easily move into silicon nitride layer 14 of charge trap insulator 16 during an erase operation.

In contrast, single electrode 18 of gate structure 100 comprises a plurality of holes rather than a plurality of electrons because single electrode 18 is doped with P-type impurities such as boron (B). Accordingly, most of the holes in single electrode 18 are positioned around a Fermi level of a P-type dopant 40, so that electron depletion is created at surface portions of single electrode 18. By further increasing the voltage applied to single electrode 18, an inversion may be generated at surface portions of single electrode 18.

Accordingly, gate structure 100 of the illustrated embodiment of FIG. 3 prevents electrons in single electrode 18 from moving into charge trap insulator 16 formed below single electrode 18 when erasing data from SONOS device unit cell 300, thereby assuring that data will be successfully erased during an erase operation of SONOS device unit cell 300.

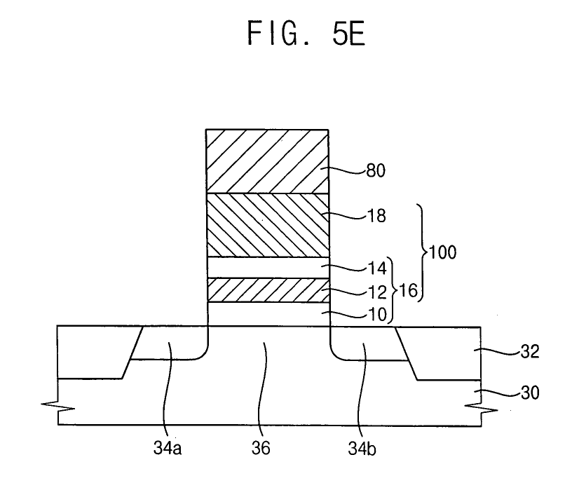

FIGS. 5A to 5E are cross-sectional views illustrating processing steps for a method of manufacturing SONOS device unit cell 300 of FIG. 3.

Referring to FIG. 5A, a device isolation layer 32, such as a trench device isolation layer, is formed in substrate 30, thereby defining an active region, on which a plurality of conductive structures may be formed, and a field region adapted to electrically isolate the active regions of substrate 30. As described above, device isolation layer 32 is a trench device isolation layer to increase the degree of integration of the SONOS memory device.

A process for forming the trench device isolation layer (i.e., device isolation layer 32) in substrate 30 will now be described. A pad oxide layer and a pad nitride layer are sequentially formed on substrate 30 and are patterned through a photolithography process, thereby forming a pad oxide pattern and a pad nitride pattern through which a surface of substrate 30 is partially exposed. An etching process is then performed on substrate 30 using the pad oxide pattern and the pad nitride pattern as an etching mask, thereby forming trenches in substrate 30. A curing process may be further performed on substrate 30 to cure any damage to substrate 30 caused by formation of the trench device isolation layer. An oxide thin layer having a good gap-filling characteristic is then formed on the resultant structure comprising the trenches to a thickness sufficient to fill the trenches through a plasma-enhanced chemical vapor deposition (PECVD) process. Then, the oxide thin layer is partially removed and planarized through a chemical mechanical polishing (CMP) process until a top surface of the pad nitride pattern is exposed. The pad nitride pattern and the pad oxide pattern are then removed from substrate 30 by a wet etching process using a phosphoric acid solution as an etchant. Accordingly, the thin oxide layer remains only in the trenches formed in substrate 30, thereby forming device isolation layer 32 (i.e., a trench device isolation layer) in substrate 30.

Referring to FIG. 5B, after device isolation layer 32 is formed in substrate 30, a first thin layer 10a comprising silicon oxide is formed on substrate 30 through a thermal oxidation process. First thin layer 10a will subsequently be formed into first silicon oxide layer 10 of charge trap insulator 16 of FIG. 3.

The thermal oxidation process for forming first thin layer 10a is performed at a relatively high temperature ranging from about 900° C. to 1,200° C. In the embodiment illustrated in FIG. 5, the thermal oxidation process is initiated at a low temperature and an operation temperature for the thermal oxidation process gradually increases to a relatively high temperature of about 900° C. to 1,200° C. so that substrate 30 does not undergo a rapid temperature variation during the thermal oxidation process. During the thermal oxidation process, the operation temperature is maintained stably, varying about ±1° C. The operation temperature is gradually decreased after first thin layer 10a is formed on substrate 30. In the embodiment illustrated in FIG. 5, oxygen (O₂) gas or water vapor (H₂O) is supplied as an oxidizing agent in the thermal oxidation process.

First thin layer 10a may have a thickness ranging, for example, from about 20 Å to 50 Å, and in particular, may have a thickness ranging from about 20 Å to 40 Å. In the embodiment illustrated in FIG. 5, first thin layer 10a is formed having a thickness of about 25 Å to 35 Å, and in particular, having a thickness of about 30 Å. In the illustrated SONOS device, electrons are trapped in charge trap insulator 16 when data is programmed into SONOS device unit cell 300, so first thin layer 10a may be formed having a relatively small thickness.

Referring to FIG. 5C, a second thin layer 12a comprising silicon nitride is formed on first thin layer 10a. Second thin layer 12a will subsequently be formed into silicon nitride layer 12 of charge trap insulator 16 of FIG. 3. A chemical vapor deposition (CVD) process may be performed to form second thin layer 12a on first thin layer 10a. The CVD process comprises a low pressure CVD (LPCVD) process and a plasma enhanced CVD (PECVD) process.

The LPCVD process may be performed, for example, at a temperature ranging from about 700° C. to 800° C. using a source gas such as SiH₂Cl₂ gas and N₂H₄ gas, and the PECVD process is performed at a temperature ranging from about 250° C. to 350° C. using a source gas such as SiH₄ gas and NH₃ gas.

Second thin layer 12a may have a thickness ranging from, for example, about 50 Å to 150 Å, and in particular, may have a thickness ranging from about 50 Å to 120 Å. In the embodiment illustrated in FIG. 5, second thin layer 12a is formed having a thickness of about 80 Å to 100 Å, and in particular, having a thickness of about 90 Å.

As illustrated in FIG. 5C, a third thin layer 14a is formed on second thin layer 12a through a radical oxidation process or a CVD process. Third thin layer 14a will subsequently be formed into third oxide layer 14 of charge trap insulator 16 of FIG. 3.

Third thin layer 14a may have a thickness ranging from, for example, about 30 Å to 60 Å, and in particular, may have a thickness ranging from about 30 Å to 50 Å. In the embodiment illustrated in FIG. 5, third thin layer 14a is formed having a thickness of about 35 Å to 45 Å, and in particular, having a thickness of about 40 Å.

Referring to FIG. 5D, a fourth thin layer 18a is formed on third thin layer 14a, and P-type impurities are doped into fourth thin layer 18a. Fourth thin layer 18a comprises a P-type impurity receptive semiconductor material.

Fourth thin layer 18a will subsequently be formed into single electrode 18 of gate structure 100 of FIG. 3. The P-type impurity receptive semiconductor material of fourth thin layer 18a comprises, for example, a composition of silicon and germanium. In the embodiment illustrated in FIG. 5, fourth thin layer 18a comprising a composition of silicon and germanium is formed on third thin layer 14a by a CVD process or a selective epitaxial growth (SEG) process, wherein the CVD or SEG process uses SiH₄ gas as a silicon source gas and GeH₄ gas as a germanium source gas.

When the silicon source gas and the germanium source gas are introduced into a process chamber at a temperature below about 350° C., reactivity of the source gases tends to be negligible, which would reduce productivity, while at a temperature over about 800° C., the reaction rate for forming fourth thin layer 18a is so rapid that it may be difficult to accurately control the final thickness of fourth thin layer 18a. Accordingly, although the CVD process or the SEG process for forming fourth thin layer 18a may be performed at other temperatures, the source gases are typically introduced into the process chamber while substrate 30 is maintained at a temperature between about 350° C. and 800° C.

The P-type impurities may be doped into fourth thin layer 18a through a diffusion process using a source gas or an ion implantation process using an ion source.

When the P-type impurities are doped into fourth thin layer 18a through a diffusion process, the source gas comprising the P-type impurities is supplied to the process chamber at the same time as the process for forming fourth thin layer 18a is performed. In the embodiment illustrated in FIG. 5, when the P-type impurities are doped into fourth thin layer 18a through a diffusion process, boron (B) is used as the P-type impurities. Examples of source gases comprising boron (B) are B₂H₆ gas and BCl₄ gas. These gases can be used alone or in a mixture thereof. Thus, the source gas comprising boron (B) is supplied to the processing chamber while the CVD or SEG process is performed to form fourth thin layer 18a on third thin layer 14a. Alternatively, an ion implantation process is performed on fourth thin layer 18a after completing the process for forming fourth thin layer 18a to dope fourth thin layer 18a with P-type impurities. In the embodiment illustrated in FIG. 5, when thin layer 18a is doped with P-type impurities through an ion implantation process, boron ions are implanted onto a surface of fourth thin layer 18a as the P-type impurities using a boron ion source gas. Examples of the boron ion source gas are B⁺, BF₂⁺, BF₃⁺, etc. These gases can be used alone or in a mixture thereof.

As described above, fourth thin layer 18a is formed on third thin layer 14a by a CVD process or an SEG process, and the P-type impurities are doped into the fourth thin layer 18a by a diffusion process or an ion implantation process. Accordingly, a semiconductor layer comprising silicon germanium doped with P-type impurities such as boron (B) is formed on third thin layer 14a as fourth thin layer 18a. As a result, a plurality of holes generated from the P-type impurities are utilized as the charge carriers in single electrode 18 of SONOS device unit cell 300 of the present invention.

Referring to FIGS. 5D and 5E, fourth thin layer 18a, third thin layer 14a, second thin layer 12a, and first thin layer 10a are sequentially patterned through a photolithography process, thereby forming first silicon oxide layer 10, silicon nitride layer 12, second silicon oxide layer 14, and single electrode 18 on substrate 30. Accordingly, charge trap insulator 16 comprising first silicon oxide layer 10, silicon nitride layer 12, and second oxide layer 14 is formed on substrate 30; and single electrode 18 is formed on charge trap insulator 16, thereby forming gate structure 100 (of FIG. 1) on substrate 30.

To form gate structure 100, a photoresist pattern 80 through which fourth thin layer 18a is partially exposed is formed on fourth thin layer 18a and an etching process is performed using photoresist pattern 80 as an etching mask. Accordingly, fourth thin layer 18a, third thin layer 14a, second thin layer 12a, and first thin layer 10a are sequentially and partially removed in accordance with photoresist pattern 80, thereby forming gate structure 100 on substrate 30.

Then, an ion implantation process is performed on substrate 30 using photoresist pattern 80 as an implantation mask so that impurities are implanted at surface portions of substrate 30 near gate structure 100, thereby forming source/drain regions 34a and 34b at surface portions of substrate 30 near gate structure 100. Examples of the impurities are phosphorus (P), arsenic (As), etc., which can be used alone or in a combination thereof. Through the ion implantation process, a channel region 36 is formed at a surface of substrate 30 between source/drain regions 34a and 34b and under gate structure 100.

Photoresist pattern 80 is then removed from single electrode 18, thereby forming SONOS device unit cell 300 of FIG. 3. SONOS device unit cell 300 comprises gate structure 100 comprising charge trap insulator 16 and single electrode 18 doped with P-type impurities. Charge trap insulator 16 comprises first silicon oxide layer 10, silicon nitride layer 12, and third silicon oxide layer 14.

In the embodiment illustrated in FIG. 3, SONOS device unit cell 300 comprises a planar type gate structure; however, a vertical type, fin type, or any other type of gate structure known to one of the ordinary skill in the art may also be used in place of or in conjunction with the planar type gate structure of SONOS device unit cell 300.

In accordance with the present invention, electrons in the single electrode may be prevented from moving into the charge trap insulator in the gate structure when erasing data from the SONOS device unit cell, thereby improving the stability of an erase operation of the SONOS device unit cell. As a result, the SONOS device may be more widely used.

Although exemplary embodiments of the present invention have been described, it will be understood that the present invention is not limited to these exemplary embodiments. Rather, various changes and modifications may be made to the exemplary embodiments by one skilled in the art while remaining within the scope of the present invention, as defined by the accompanying claims.

What is claimed is:

1. A gate structure comprising:
a charge trap insulator comprising a multilayer structure comprising a first silicon oxide layer, a silicon nitride layer, and a second silicon oxide layer; and,
a single electrode formed on the charge trap insulator and comprising a P-type impurity receptive semiconductor material.

2. The gate structure of claim 1, wherein the P-type impurity receptive semiconductor material comprises a composition of silicon and germanium.

3. The gate structure of claim 1, wherein the P-type impurity receptive semiconductor material is doped with boron (B).

4. A non-volatile memory device comprising:
a semiconductor substrate;
source/drain regions disposed in the substrate and doped with N-type impurities;
a channel region disposed in the substrate between the source/drain regions; and,
a gate structure formed on the channel region, wherein the gate structure comprises:
a multilayer charge trap insulator comprising a first silicon oxide layer, a silicon nitride layer, and a second silicon oxide layer; and,
a single electrode formed on the charge trap insulator and comprising a P-type impurity receptive semiconductor material.

5. The non-volatile memory device of claim 4, wherein the N-type impurities comprise at least one of phosphorus (P) or arsenic (As).

6. The non-volatile memory device of claim 5, wherein the P-type impurity receptive semiconductor material comprises a composition of silicon and germanium.

7. The non-volatile memory device of claim 5, wherein the P-type impurity receptive semiconductor material is doped with boron (B).

8. A method of manufacturing a non-volatile memory device comprising:
sequentially forming a first thin layer comprising silicon oxide, a second thin layer comprising silicon nitride, and a third thin layer comprising silicon oxide on a semiconductor substrate;
forming a fourth thin layer on the third thin layer, wherein the fourth thin layer comprises a P-type impurity receptive semiconductor material;
doping the fourth thin layer with P-type impurities;
sequentially and partially etching the fourth thin layer, the third thin layer, the second thin layer, and the first thin layer to form a gate structure on the semiconductor substrate comprising a single electrode and a charge trap insulator, wherein the charge trap insulator comprises a first silicon oxide layer, a silicon nitride layer, and a second silicon oxide layer; and,
implanting N-type impurities into the substrate to form source/drain regions proximate the gate structure.

9. The method of claim 8, wherein forming the first thin layer comprises performing a thermal oxidation process.

10. The method of claim 8, wherein the P-type impurity receptive semiconductor material comprises a composition of silicon and germanium.

11. The method of claim 10, wherein forming the fourth thin layer comprises performing a chemical vapor deposition (CVD) process or a selective epitaxial growth (SEG) process.

12. The method of claim 8, wherein the P-type impurities comprise boron (B).

13. The method of claim 8, wherein doping the fourth thin layer with P-type impurities comprises performing a diffusion process using a source gas comprising P-type impurities supplied to a process chamber at the same time as the fourth thin layer is formed on the third thin layer.

14. The method of claim 13, wherein the source gas comprises at least one of B₂H₆, or BCl₄.

15. The method of claim 8, wherein doping the fourth thin layer with P-type impurities is performed after the fourth thin layer is formed, and wherein doping the fourth thin layer with P-type impurities comprises performing an ion implantation process using an ion source gas comprising P-type impurities.

16. The method of claim 15, wherein the ion source gas comprises at least one gas selected from a group consisting of B⁺, BF₂⁺, and BF₃⁺.

17. The method of claim 8, wherein the N-type impurities comprise at least one of phosphorus (P) or arsenic (As).
